(19) United States
(12) Patent Application Publication
(10) Pub. No.: US 2011/0198569 A1
(43) Pub. Date: Aug. 18, 2011

(54) APPARATUS AND METHODS OF NANOPATTERNING AND APPLICATIONS OF SAME

(75) Inventors: Ajay P. Malshe, Fayetteville, AR (US); Curtis R. Taylor, Fayetteville, AR (US); Gregory Salamo, Fayetteville, AR (US); Eric Stach, West Lafayette, IN (US); Robin Prince, Cambridge, MA (US); Zhiming Wang, Fayetteville, AR (US)

(73) Assignee: BOARD OF TRUSTEES OF THE UNIVERSITY OF ARKANSAS, Little Rock, AR (US)

(21) Appl. No.: 12/922,331

(22) PCT Filed: Mar. 6, 2009
(86) PCT No.: PCT/US09/36362

§ 371 Date: May 2, 2011

Related U.S. Application Data
(60) Provisional application No. 61/036,815, filed on Mar. 14, 2008.

(51) Int. Cl. H01L 29/66; H01L 21/20; B05C 11/00; B82Y 40/00; B82Y 99/00

(52) U.S. Cl. 257/15; 438/478; 257/12; 257/9; 118/44; 257/E21.09; 257/E29.168; 977/819; 977/825; 977/890; 977/932

(57) ABSTRACT

A method for patterning nanostructures in a semiconductor heterostructure, which has at least a first layer and a second layer, wherein the first layer has a first surface and an opposite, second surface, the second layer has a first surface and an opposite, second surface, and the first layer is deposited over the second layer such that the second surface of the first layer is proximate to the first surface of the second layer. The method includes the steps of making indentations in a pattern on the first surface of the first layer of the semiconductor heterostructure; bonding the semiconductor heterostructure to a support substrate such that the first surface of the first layer of the semiconductor heterostructure is faced to the support substrate; etching off the second layer of the semiconductor heterostructure; and depositing a third layer over the second surface of the first layer of the semiconductor heterostructure.

### CROSS-REFERENCE TO RELATED PATENT APPLICATION

This application claims the benefit, pursuant to 35 U.S.C. §119(e), of provisional U.S. patent application Ser. No. 61/036,815, filed 14 Mar. 2008, entitled “Quantum Dots, Nanopatterning, Apparatus, Methods and Applications of Same” by Gregory Salamo, Curtis R. Taylor, Ajay P. Malshe, Eric Stach, Robin Prince, and Zhiming Wang, which is incorporated herein by reference in its entirety.

### STATEMENT OF FEDERALLY-SPONSORED RESEARCH

This invention was made with government support under grant number 9972820 awarded by National Science Foundation—Integrative Graduate Education and Research Training (IGERT). The government has certain rights in the invention.

This application is being filed as PCT International Patent application in the name of Board of Trustees of the University of Arkansas, a U.S. national corporation, Applicant for all countries except the U.S., and Ajay P. Malshe, Gregory Salamo, Curtis R. Taylor, Eric Stach, Robin Prince and Zhiming Wang, all residents of the United States of America, Applicants for the designation of the U.S. only, on 6 Mar. 2009.

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference. In terms of notation, hereinafter, “[n]” represents the nth reference cited in the reference list. For example, [3] represents the 3rd reference cited in the reference list, namely, D. Leonard, M. Krishnamurthy, C. M. Reaves, S. P. Denbaars, and P. M. Petroff, Appl. Phys. Lett. 63, 3203 (1993).

### BACKGROUND OF THE INVENTION

The ability to pattern self-assembled low-dimensional semiconductor nanostructures is extremely important for the realization of novel electronic and photonic device technologies [1, 2]. Self-assembly via the Stanski-Krastanow growth mode [3] results in spontaneously nucleated structures, such as quantum dots (QDs) or wires, which are randomly distributed on the epitaxial surface. Also, the nanostructure size and morphology are highly dispersive. For device applications, precise control of quantum structure size, location, and arrangement is critical and needs an effective bias to tailor self-assembly.

Recent work has shown that guided self-assembly and spatial patterning are achieved by the formation of subsurface misfit dislocations [4-7]. The localized elastic strain fields of dislocations provide strain-relaxed surface sites that enhance surface atom migration resulting in specific patterns. Elasticity calculations and transmission electron microscopy (TEM) show that the linear QD chains are aligned with the underneath dislocations. However, precise spatial control of misfit dislocations is not feasible due to the arbitrary formation of dislocation sources at the heterointerface. Thus the patterns formed are irregular. If the placement and formation of subsurface dislocations can be controlled, then it would be a highly effective patterning mechanism.

Therefore, a heretofore unaddressed need exists in the art to address the aforementioned deficiencies and inadequacies.

### SUMMARY OF THE INVENTION

The present invention, in one aspect, relates to a method for patterning nanostructures in a semiconductor heterostructure, which has at least a first layer and a second layer, wherein the first layer has a first surface and an opposite, second surface, the second layer has a first surface and an opposite, second surface, and the first layer is deposited over the second layer such that the second surface of the first layer is proximate to the first surface of the second layer.

In one embodiment, the method includes the steps of making indentations in a pattern on the first surface of the first layer of the semiconductor heterostructure; bonding the semiconductor heterostructure to a support substrate such that the first surface of the first layer of the semiconductor heterostructure is faced to the support substrate; etching off the second layer of the semiconductor heterostructure; and depositing a third layer over the second surface of the first layer of the semiconductor heterostructure to allow nanostructures to grow in a pattern thereon a surface of the third layer which is distant away from the second surface of the first layer. The first to third layers comprise a GaAs layer, an AlAs layer and an InAs layer, respectively.

In one embodiment, the making step comprises the steps of positioning an indenter over the first surface of the first layer of the semiconductor heterostructure at a desired position; applying a load to the indenter to produce an indentation at the desired position; and repeating steps (a) and (b) to make indentations in a desired pattern, wherein the nanostructures are grown in a pattern corresponding to the indentations in a desired pattern.

The indenter comprises a nanoscale tip capable of producing a desired indention, wherein the nanoscale tip has an end profile of one of a circle, square, triangle, rhombus, pyramid, cube corner, polygon and a desired geometric shape.

The load applied is less than a threshold value.

The nanostructures comprise quantum dots, nanowires, nanorods, or nanotubes.

In one embodiment, the method further comprises the steps of depositing a fourth layer over the grown nanostructures on the third layer; and depositing a fifth layer over the fourth layer to allow nanostructures to grow 3-dimensionally therein, wherein the fourth and fifth layers comprise a GaAs layer and an InAs layer, respectively.

The present invention, in another aspect, relates to an apparatus for patterning nanostructures in a semiconductor heterostructure. In one embodiment, the apparatus includes a positioning device capable of moving in three dimensions; an indenter coupled to the position device; a load device for applying a load to the indenter for producing an indentation on a surface of the semiconductor heterostructure; a controller in communication with the positioning device for controlling the indenter to move to a desired position over the surface of the semiconductor heterostructure to produce an indentation thereon; and means for depositing a semiconductor layer over the indented surface of the semiconductor heterostructure as to allow nanostructures to grow from another surface of the semiconductor heterostructure that is opposite to the indented surface.

The semiconductor heterostructure comprises a GaAs buffer layer having a thickness substantially around 500 nm grown on an epiready Si-doped GaAs(100) wafer, an AlAs marker layer having a thickness substantially around 100 nm deposited on the GaAs buffer layer, and a GaAs top layer having a thickness substantially around 300 nm deposited on the AlAs marker layer.

The indenter comprises a nanoscale tip capable of producing a desired indention, and wherein the nanoscale tip has an end profile of one of a circle, square, triangle, rhombus, pyramid, cube corner, polygon and a desired geometric shape.

The present invention, in a further aspect, relates to a method for patterning nanostructures in a semiconductor. In one embodiment, the method includes the steps of indenting a surface of the semiconductor to make nano-sized volumes of dislocations thereon in a desired pattern, and forming a semiconductor layer over the indented surface of the semiconductor to allow nanostructures to grow corresponding to the desired pattern on another surface of the semiconductor that is opposite to the indented surface.

The present invention, in yet another aspect, relates to a method for growing nanostructures in a pattern with a semiconductor heterostructure that has at least a first layer and a second layer, wherein the first layer has a first surface and an opposite, second surface, the second layer has a first surface and an opposite, second surface, and the first layer is deposited over the second layer such that the second surface of the first layer is proximate to the first surface of the second layer. In one embodiment, the method includes the steps of making indentations in a pattern on the first surface of the first layer of the semiconductor heterostructure, and growing nanostructures at a surface that is separated from the first surface of the first layer of the semiconductor heterostructure, wherein each nanostructure grows at a position corresponding to one of the indentations.

The step of growing nanostructures includes the steps of (a) bonding a third layer with the first layer, (b) forming a fourth layer over the third layer, and (c) growing nanostructures at a surface of the fourth layer that is distant away and separated from the first layer. The nanostructures as grown form a pattern that is substantially identical to the pattern of the indentations.

In one embodiment, the third and fourth layers comprise a GaAs layer and an InAs layer, respectively. And the method further comprises the steps of depositing a fifth layer of GaAs over the grown nanostructures on the fourth layer of InAs, and depositing a sixth layer of InAs over the fifth layer of GaAs to allow nanostructures to grow therein at positions corresponding to the positions of the nanostructures on the fourth layer of InAs, wherein the fifth layer and sixth layer form a combination of a layer of GaAs and a layer of InAs with nanostructures grown on the layer of InAs. The method further comprises the step of depositing additional a combination of a layer of GaAs and a layer of InAs over the last combination of a layer of GaAs and a layer of InAs.

The present invention, in yet a further aspect, relates to a semiconductor heterostructure formed with nanostructures. In one embodiment, the semiconductor heterostructure has a first layer having a first surface and an opposite, second surface, and a second layer having a first surface and an opposite, second surface, wherein the first layer is deposited over the second layer such that the second surface of the first layer is distant from the second layer. The semiconductor heterostructure further has at least one indentation formed on the first surface of the first layer, a third layer deposited over the second surface of the first layer, wherein the third layer has a first surface and an opposite, second surface, and the third layer is deposited over the second surface of the first layer such that the second surface of the third layer is in contact with the second surface of the first layer, and at least one nanostructure formed on the first surface of the third layer and at a position corresponding to that of at least one indentation formed on the first surface of the first layer. The first to third layers comprise a GaAs layer, an AlAs layer and an InAs layer, respectively.

The at least one indentation formed on the first surface of the first layer comprises one or more indentations formed in a pattern or an array.

The at least one nanostructure comprises one or more nanostructures formed in a pattern or an array corresponding to the pattern or array the one or more indentations formed, wherein the nanostructures comprise quantum dots, nanowires, nanorods, or nanotubes.

The present invention, in yet another aspect, relates to a semiconductor heterostructure formed with nanostructures. In one embodiment, the semiconductor heterostructure has a first layer having a first surface and an opposite, second surface, at least one indentation formed on the first surface of the first layer, and a second layer formed over the first surface of the first layer, wherein the second layer is a buffer layer. The semiconductor heterostructure further has a layered structure formed over the second layer, wherein the layered structure has at least a first layer of a first semiconductor, a second layer of the first semiconductor, and a layer of a second semiconductor positioned between the first layer and the second layer of the first semiconductor, and at least one nanostructure formed on each of a first surface of the first layer and the second layer of the first semiconductor, respectively, and at a position corresponding to that of at least one indentation formed on the first surface of the first layer. The first layer comprises a layer of MBE GaAs or VGF GaAs, the second layer comprises a layer of GaAs, the first semiconductor comprises InAs, and the second semiconductor comprises GaAs, respectively.

The at least one indentation formed on the first surface of the first layer comprises one or more indentations formed in a pattern or an array.

The at least one nanostructure comprises one or more nanostructures formed in a pattern or an array corresponding to the pattern or array the one or more indentations formed, wherein the nanostructures comprise quantum dots, nanowires, nanorods, or nanotubes.

The semiconductor heterostructure has a super-lattice structure.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

FIG. 1 shows schematically a method for patterning quantum dots according to one embodiment of the present invention: (a)-(d) different steps.

FIG. 2 shows schematically a method for patterning quantum dots according to one embodiment of the present invention: (a)-(d) different materials.

FIG. 3(a) shows an SEM image (side-view) of final thinned GaAs sample, and FIG. 3(b) shows an equivalent low magnification TEM image of the sample shown in part (a) revealing indents (arrowed) and subsurface deformation.

FIG. 4 shows plots of residual indent dimensions in GaAs(100) measured by AFM.

FIG. 5 shows bright-field TEM images (g=220 diffraction condition) of cube corner indents on the GaAs(100) surface at indentation loads of (a) 400 μN inset image shows the zone axis diffraction pattern taken from central indent area labeled (1), (b) 200 μN, and (c) 100 μN. The platinum layer is denoted by Pt in all of the images.

FIG. 6 shows (a) AFM image of 400 μN indentation array with indents spaced 1 μm apart, and (b) bright-field (g=400 diffraction condition) TEM image of 400 μN indents showing subsurface dislocation array.

FIG. 7 shows STM images of VGF GaAs(100) surface: (a) plan-view, (b) surface profile, and (c) 3D view of surface.

FIG. 8 shows STM images of MBE GaAs(100) surface: (a) plan-view, (b) surface profile, and (c) 3D view of surface.

FIG. 9 shows load-displacement curves of (a) VGF GaAs(100) and (b) MBE GaAs(100) at a maximum depth of 50 nm, and (c) VGF GaAs(100) and (d) MBE GaAs(100) at a maximum depth of 33 nm.

FIG. 10 shows load-depth curves for indentations from 400 to 25 μN.

FIG. 11 shows AFM images of the surface of (a) 5 μN and (b) 25 μN indents on GaAs(100).

FIG. 12 shows a plot of final indent depth as indicated by load-depth curves versus measured residual depth.

FIG. 13 is an AFM section analysis of an indentation showing a typical cross-section used for residual depth and width measurements.

FIG. 14 shows AFM images of (a) 400 μN, (b) 300 μN, (c) 200 μN, and (d) 75 μN indents on the GaAs(100) surface.

FIG. 15 shows indent and pile-up volume versus applied load.

FIG. 16 shows cross-section line scans and AFM images of (a) 25 μN and (b) 15 μN indents.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise.

### DEFINITIONS

The terms used in this specification generally have their ordinary meanings in the art, within the context of the invention, and in the specific context where each term is used.

Certain terms that are used to describe the invention are discussed below, or elsewhere in the specification, to provide additional guidance to the practitioner in describing the apparatus and methods of the invention and how to make and use them. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that the same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification, including examples of any terms discussed herein, is illustrative only, and in no way limits the scope and meaning of the invention or of any exemplified term. Likewise, the invention is not limited to various embodiments given in this specification. Furthermore, subtitles may be used to help a reader of the specification to read through the specification, which the usage of subtitles, however, has no influence on the scope of the invention.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “atomic force microscope (AFM)” or scanning force microscope (SFM) refers to a very high-resolution type of scanning probe microscope, with demonstrated resolution of fractions of a nanometer, more than 1000 times better than the optical diffraction limit. The term “microscope” in the name of “AFM” is actually a misnomer because it implies looking, while in fact the information is gathered or the action is taken by “feeling” the surface with a mechanical probe. The AFM in general has a microscale cantilever with a tip portion (probe) at its end that is used to scan the specimen surface. The cantilever is typically silicon or silicon nitride with a tip radius of curvature on the order of nanometers. When the tip is brought into proximity of a sample surface, forces between the tip and the sample lead to a deflection of the cantilever according to Hooke's law. The AFM can be utilized in a variety of applications.

As used herein, the term “transmission electron microscopy (TEM)” refers to a microscopy technique whereby a beam of electrons is transmitted through an ultra thin specimen, interacting with the specimen as it passes through it. An image is formed from the electrons transmitted through the specimen, magnified and focused by an objective lens and appears on an imaging screen, a fluorescent screen in most TEMs, plus a monitor, or on a layer of photographic film, or to be detected by a sensor such as a CCD camera.

As used herein, the term “scanning electron microscope (SEM)” refers to a type of electron microscope that images the sample surface by scanning it with a high-energy beam of electrons in a raster scan pattern. The electrons interact with the atoms that make up the sample producing signals that contain information about the sample's surface topography, composition and other properties such as electrical conductivity.

As used herein, the term “scanning tunneling microscope (STM)” is a technique for viewing surfaces at the atomic level. STM probes the density of states of a material using tunneling current. The STM is based on the concept of quantum tunneling. When a conducting tip is brought very near to a metallic or semiconducting surface, a bias between the two can allow electrons to tunnel through the vacuum between them. For low voltages, this tunneling current is a function of the local density of states (LDOS) at the Fermi level, E_{f}, of the sample. Variations in current as the probe passes over the surface are translated into an image.

As used herein, the term “Group” is given its usual definition as understood by one of ordinary skill in the art. For instance, Group II elements include Zn, Cd and Hg; Group III elements include B, Al, Ga, In and Tl; Group IV elements include C, Si, Ge, Sn and Pb; Group V elements include N, P, As, Sb and Bi; and Group VI elements include O, S, Se, Te and Po. Combinations involving more than one element from each group are also possible. For example, a Group II-VI material may include at least one member from Group II and at least one member from Group VI, for example, ZnS, ZnSe, ZnSSe, ZnCdS, CdS, or CdSe. Similarly, a Group III-V material may comprise at least one member from Group III and at least one member from Group V, for example GaAs, GaP, GaAsP, InAs, InP, AlGaAs, or InAsP. Other dopants may also be included with these materials and combinations thereof, for example, transition metals such as Fe, Co, Te, Au, and the like.

As used herein, “nanoscopic-scale,” “nanoscopic,” “nanometer-scale,” “nanoscale,” the “nano-” prefix, and the like generally refers to elements or articles having widths or diameters of less than about 1 μm, preferably less than about 100 nm in some cases. In all embodiments, specified widths can be smallest width (i.e. a width as specified where, at that location, the article can have a larger width in a different dimension), or largest width (i.e. where, at that location, the article's width is no wider than as specified, but can have a length that is greater).

As used herein, the term “quantum well” refers to a double heterojunction structure including an ultrathin layer of a semiconductor material sandwiched by a first outer layer of a semiconductor material and a second outer layer of a semiconductor material, where the bandgap of the ultrathin layer of the semiconductor material is smaller than that of the first outer layer of the semiconductor material and the second outer layer of the semiconductor material. The sandwiched structure forms conduction band and valence band potential wells within which electrons are confined in the conduction band potential well and holes are confined in the valence band potential well, respectively. A quantum well is a potential well that confines carriers (electrons, holes, or electron-hole pairs) therein, forcing them to occupy a planar region.

The term “quantum dot” or “QD”, as used herein, refers to a heterojunction structure having potential wells formed such that carriers (electrons, holes, or electron-hole pairs) are confined in a small region in all three dimensions. This confinement leads to discrete quantized energy levels and to the quantization of charge in units of the elementary electric charge, e. Because the quantum dot has discrete energy levels, much like an atom, it is sometimes called “an artificial atom”. The energy levels of the quantum dot can be controlled by changing the size and shape of the quantum dot, and the depth of the potential.

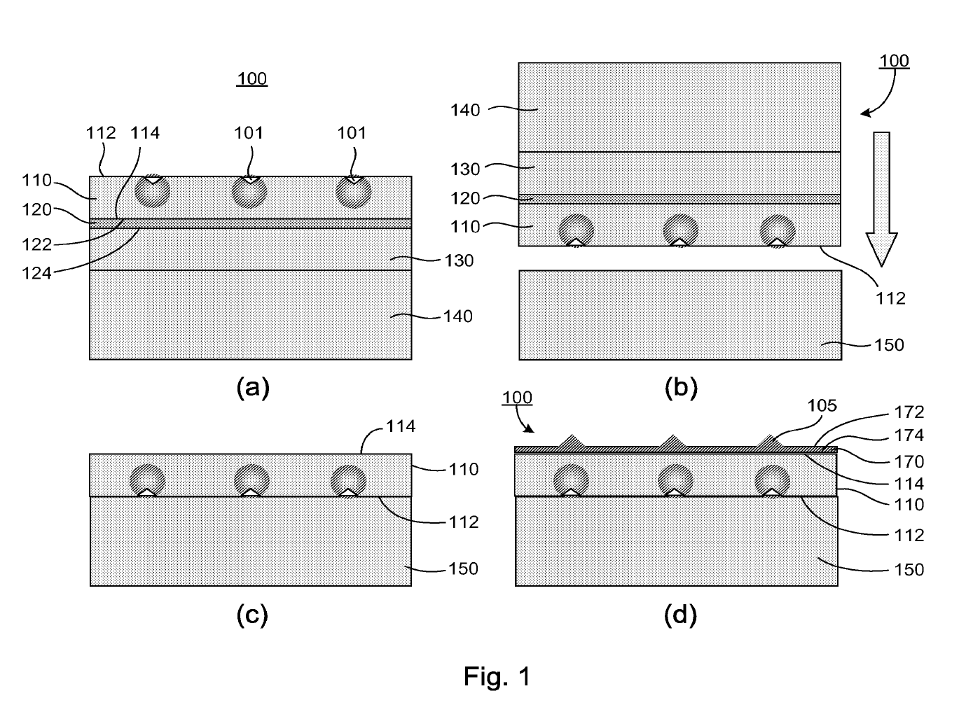

The description will be made as to the embodiments of the present invention in conjunction with the accompanying drawings in FIGS. 1-16. In accordance with the purposes of this invention, as embodied and broadly described herein, this invention, in one aspect, relates to a method for patterning nanostructures in a semiconductor hetero structure.

Referring first to FIG. 1, a semiconductor heterostructure 100 formed with nanostructures according to one aspect of the present invention, is shown. In this embodiment as shown, the semiconductor heterostructure 100 has a first layer 110 having a first surface 112 and an opposite, second surface 114, and a second layer 150 having a first surface and an opposite, second surface, where the first layer 110 is formed over the second layer 150 such that the second surface 114 of the first layer 110 is distant from the second layer 150. The semiconductor heterostructure 100 further has at least one indentation 101 formed on the first surface 112 of the first layer 110. The at least one indentation 101 formed on the first surface 112 of the first layer 110 includes one or more indentations formed in a pattern or an array. As such formed, the surface having the indentations 101, i.e., the first surface 112 of the first layer 110, is in contact with the second layer 150.

A third layer 170 is formed over the second surface 114 of the first layer 110, where the third layer 170 has a first surface 172 and an opposite, second surface 174, and the third layer 170 is formed over or on the second surface 114 of the first layer 110 such that the second surface 174 of the third layer 170 is in contact with the second surface 114 of the first layer 110. The semiconductor heterostructure 100 further has at least one nanostructure 105 grown and formed on the first surface 172 of the third layer 170 and at a position corresponding to that of at least one indentation 101 formed on the first surface 112 of the first layer 110. The at least one nanostructure 105 grown and formed on the first surface 172 of the third layer 170 includes one or more nanostructures 105 formed in a pattern or an array at positions corresponding to the positions of the indentations formed 101 in a pattern or an array. The nanostructures 105 can be grown by selective etching and water bonding.

Among other things, thus, one unique feature of the semiconductor heterostructure 100 is that the nanostructures 105 are formed on a “back-side” of the indented surface 112 but with positions corresponding to those of the indentations on the indented surface 112; in other words, in contrast to the existing technology to grow nanostructures on an indented surface or directly from the indentations created on that indented surface, nanostructures of the present invention are formed at a surface that is on a back-side of the indented surface and physically apart from that indented surface. For the embodiment shown in FIG. 1(d), the surface 172 with nanostructures 105 thereon is on the back-side of the indented surface 112 and is at least separated by the layer 170 from the indented surface 112.

Several unexpected advantages are produced by such a semiconductor heterostructure 100 that has the nanostructures formed on a “back-side” of the indented surface: first, the “back-side” growth of the nanostructures prevents dislocations from migrating into the grown nanostructures, which allows for a coherent and electrically/optically active structure to be available. Second, such a structure can be produced in a scalable process potentially allowing for fast and cheaper production of nanostructures in dense large-scale patterns. Moreover, such formed nano stamping/nano indention can be utilized as means for nano patterning and nano stamping for functional transformation.

Each of the first layer 110, the second layer 150 and the third layer 170 can be made from a Group III-V material, for example GaAs, GaP, GaAsP, InAs, InP, AlGaAs, AlAs or InAsP. For examples, in the exemplary embodiment as shown in FIG. 1, the first layer 110 of the semiconductor heterostructure 100 is a GaAs layer, the second layer 150 of the semiconductor heterostructure 100 is an AlAs layer, and the third layer 170 of the semiconductor heterostructure 100 is an InAs layer, respectively.

The nanostructures grown can be quantum dots, nanowires, nanorods, or nanotubes. In the exemplary embodiment as shown in FIG. 1, the nanostructures 105 of the semiconductor heterostructure 100 are quantum dots of InGaAs.

Such a semiconductor heterostructure 100 can be made by a method according to on embodiment o the present invention. Still referring to FIGS. 1(a)-(d), a semiconductor heterostructure is provided with a first layer 110 and a second layer 120, where the first layer 110 has a first surface 112 and an opposite, second surface 114, the second layer 120 has a first surface 122 and an opposite, second surface 124, and the first layer 110 is deposited over the second layer 120 such that the second surface 114 of the first layer 110 is proximate to the first surface 122 of the second layer 120. Both of the first and second layers can be made from different materials, in particular, materials from Group III-V materials. In this exemplary embodiment, the first layer 110 is a GaAs top layer having a thickness substantially around 300 nm, the second layer 120 is an AlAs marker layer having a thickness substantially around 100 nm deposited on a GaAs buffer layer, which is layer 130 as shown in FIG. 1(a). The GaAs buffer layer in this embodiment has a thickness substantially around 500 nm. The combined structure of the first layer 110, the second layer 120, and the buffer layer 130 can be supported by a substrate 140, which in one embodiment is a GaAs (100) substrate.

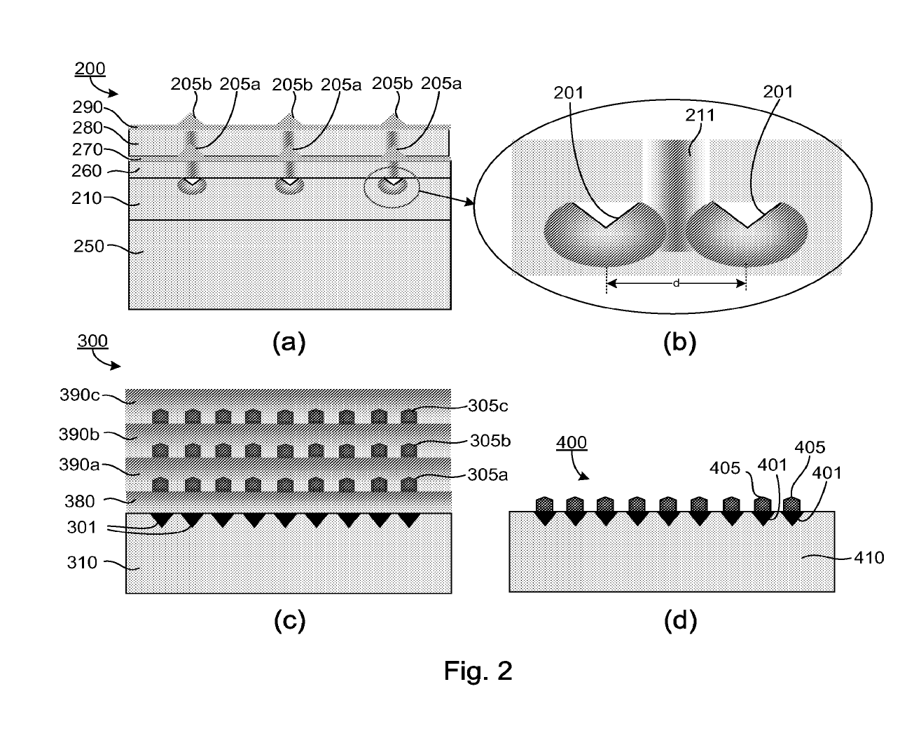

In one embodiment, the method includes the steps of making one or more indentations 101 in a pattern on the first surface 112 of the first layer 110 of the combined structure. In an exemplary embodiment, indentations are made in an array that has a neighboring distance, d, between two neighboring indentations about 1 μm, as shown in FIG. 2(b).

In one embodiment, the indentations 101 can be made by positioning an indenter over the first surface 112 of the first layer 110 of the semiconductor heterostructure 100 at a desired position, applying a load to the indenter to produce an indentation 101 at the desired position, and repeating these steps to make indentations in a desired pattern, where a controller is programmed to control and coordinate the process of making the indentations in the desired pattern. The load applied is less than a threshold value that, as known to people skilled in the art, among other things, is related to the dimensions of the indentations. The indenter has a nanoscale tip that is capable of producing a desired indention, wherein the nanoscale tip has an end profile of one of a circle, square, triangle, rhombus, pyramid, cube corner, polygon and a desired geometric shape. In one embodiment, a nanoscale tip that has an end profile of a square is chosen to produce square indentations for the patterning of nanostructures. The symmetry of the square indent allows for the nucleation of nanostructures at each of the corners of the square. Nevertheless, as set forth above and below, nanoscale tips having an end profile of other desired geometries can be also utilized to practice the present invention.

When a load is applied to the indenter, the nanoscale tip mechanically contacts with the surface to be indented at a desired location and deforms the surface to create nano-sized columes of dislocations or indentations. The strain fields from the dislocations are used to bias nucleation and self-assembly of nanostructures. In one embodiment as shown in FIG. 2(b), strain field 211 is shown to probably have maximum strength between, around or at the indentations.

Once the indentations are formed on the first surface 112 of the first layer 110 of the combined structure with the substrate 140, as shown in FIG. 1(b), it can be bonded to a support substrate 150 such that the first surface 112 of the first layer 110 is faced to the support substrate 150. Then, the second layer 120 of the combined structure with the substrate 140, here a layer of AlAs in this embodiment, is laterally etched off and the layer 130 and layer 140 are removed, which allows the back-side, i.e., surface 114, of the surface 112 with indents 101 of the layer 110 is exposed or revealed as shown in FIG. 1(c). Next, a third layer 170 is deposited over the second surface 114 of the first layer 110 to allow nanostructures 105 to grow thereon a surface 172 of the third layer 170 corresponding to the locations of indentations 101, which is distant away from the second surface 114 of the first layer 110. The surface 174, which is opposite to the surface 172, is in contact with the second surface 114 of the first layer 110. As such, a semiconductor heterostructure 100 with nanostructures 105 formed in a pattern or array is formed as shown in FIG. 1(d). In one embodiment, the third layer 170 is an InAs layer, and the nanostructures 105 grown thereon are InGaAs quantum dots.

The present invention, thus, in another aspect, relates to an apparatus for patterning nanostructures in a semiconductor heterostructure. In one embodiment, the apparatus includes a positioning device capable of moving in three dimensions; an indenter coupled to the position device, a load device for applying a load to the indenter for producing an indentation on a surface of the semiconductor heterostructure, a controller in communication with the positioning device for controlling the indenter to move to a desired position over the surface of the semiconductor heterostructure to produce an indentation thereon, and means for depositing a semiconductor layer over the indented surface of the semiconductor heterostructure as to allow nanostructures to grow from another surface of the semiconductor heterostructure that is opposite to the indented surface.

The present invention, in a further aspect, relates to a method for patterning nanostructures in a semiconductor. In one embodiment, the method includes the steps of indenting a surface of the semiconductor to make nano-sized volumes of dislocations thereon in a desired pattern, and forming a semiconductor layer over the indented surface of the semiconductor to allow nanostructures to grow corresponding to a desired pattern on another surface of the semiconductor that is opposite to the indented surface.

The present invention, in yet another aspect, relates to another method for growing nanostructures in a pattern with a semiconductor heterostructure, referring now to FIGS. 2(a)-(d). A semiconductor heterostructure 200 is provided with a first layer 210 and a second layer 250, wherein the first layer 210 has a first surface and an opposite, second surface, the second layer 250 has a first surface and an opposite, second surface, and the first layer 210 is deposited over the second layer 250 such that the second surface of the first layer 210 is proximate to the first surface of the second layer 250. In one embodiment, the method includes the steps of making indentations 201 in a pattern on the first surface of the first layer 210 of the semiconductor heterostructure, and growing nanostructures 205a at a surface that is separated from the first surface of the first layer 210 of the semiconductor heterostructure, wherein each nanostructure 205a grows at a position corresponding to that of one of the indentations 201.

In particular, nanostructures 205a can be grown by (a) bonding a third layer 260 with the first layer 210, (b) forming a fourth layer 270 over the third layer 260, and (c) growing nanostructures 205a at a surface of the fourth layer 270 that is distant away and separated from the first layer 210. The nanostructures 205a as grown form a pattern that is substantially identical to the pattern of the indentations 201.

Both of the third and fourth layers can be made from different materials, in particular, materials from Group III-V materials. In one exemplary embodiment, the third layer 260 is a GaAs layer with a thickness of about 5-20 nm, functioning as a buffer layer. And the fourth layer is an InAs layer, on which the nanostructures 205a, here InAs quantum dots, are grown in a pattern or an array.

Additional nanostructures can be further grown by utilizing the steps as set forth above. In one exemplary embodiment, still referring to FIG. 2(a), a fifth layer 280 of a material substantially similar to that of the layer 260, which is a layer of GaAs layer as shown, is formed over the grown nanostructures 205a on the fourth layer 270 of InAs. And a sixth layer 290 of a material substantially similar to that of the layer 270, which is a layer of InAs layer as shown, is formed over the fifth layer 280 of GaAs to allow nanostructures 205b to grow therein at positions corresponding to the positions of the nanostructures 205a on the fourth layer 270 of InAs. In other words, as show in this exemplary embodiment, the fifth layer 280 and sixth layer 290 form a combination of a layer of GaAs and a layer of InAs with nanostructures 205b grown on the layer of InAs. The process can be repeated by depositing additional a combination of a layer of GaAs and a layer of InAs over the last combination of a layer of GaAs and a layer of InAs to form a semiconductor heterostructure formed with nanostructures and having a periodic structure, or a superlattice.

Several semiconductor heterostructures formed with nanostructures according to various embodiments are shown in FIGS. 2(a), 2(c) and 2(d), respectively. In one embodiment as shown in FIG. 2(a), as already discussed above, the semiconductor heterostructure 200 has a first layer 210 having a first surface and an opposite, second surface, one or more indentations 201 formed on the first surface of the first layer 210, and a second layer 260 formed over the first surface of the first layer 210, where the second layer 260 is a buffer layer.

The semiconductor heterostructure 200 further has a layered structure formed over the second layer 260, where the layered structure has at least a first layer 270 of a first semiconductor, a second layer 290 of the first semiconductor, and a layer 280 of a second semiconductor positioned between the first layer 270 and the second layer 290 of the first semiconductor. One or more nanostructures 205a, 205b formed on each of a first surface of the first layer 270 and the second layer 290 of the first semiconductor, respectively, and at a position corresponding to that of at least one indentation 201 formed on the first surface of the first layer 210. In the embodiment as shown in FIG. 2(a), one or more nanostructures 205a are formed on a first surface of the first layer 270, and one or more nanostructures 205b are formed on a first surface of the second layer 290 of the first semiconductor, respectively. Each of the nanostructures 205a is formed at a position corresponding to that of a corresponding one of indentations 201 formed on the first surface of the first layer 210, and each of the nanostructures 205b is formed at a position corresponding to that of one of the nanostructures 205a, and thus also corresponding to that of a corresponding one of indentations 201 formed on the first surface of the first layer 210.

In the embodiment as shown in FIG. 2(a), the first layer of this layered structure is a layer of MBE GaAs, the second layer is a layer of GaAs, the first semiconductor comprises InAs, and the second semiconductor comprises GaAs, respectively.

In another embodiment as shown in FIG. 2(c), a semiconductor heterostructure 300 has a first layer 310 having a first surface and an opposite, second surface, one or more indentations 301 formed on the first surface of the first layer 310. The semiconductor heterostructure 300 further has a layered structure 390a formed over the first layer 310. The layered structure 390a has a first layer of a first semiconductor and a second layer of the first semiconductor. A layer 380 of a second semiconductor is positioned between the first layer 310 and the second layer of the first semiconductor of the layered structure 390a. One or more nanostructures 305a are formed on a first surface of the layer 380, and one or more nanostructures 305b are formed on a first surface of the second layer of the first semiconductor of the layered structure 390a, respectively. Each of the nanostructures 305a is formed at a position corresponding to that of a corresponding one of indentations 301 formed on the first surface of the first layer 310, and each of the nanostructures 305b is formed at a position corresponding to that of one of the nanostructures 305a, and thus also corresponding to that of a corresponding one of indentations 301 formed on the first surface of the first layer 310.

The semiconductor heterostructure 300 further has additional layered structures 390b (with nanostructures 305c), 390c formed over the layered structure 390a in a stacked fashion to form a superlattice and to allow nanostructures 305a, 305b, 305c, . . . , to grow 3-dimensionally. Additional layered structures can be added on to the semiconductor heterostructure 300.

In the embodiment as shown in FIG. 2(c), the first layer 310 is layer of VGF GaAs (100), the layer 380 is a layer of MBE GaAs as a buffer layer, the first semiconductor comprises InAs, and the second semiconductor comprises GaAs, respectively.

In yet another embodiment as shown in FIG. 2(d), a semiconductor heterostructure 400 has a first layer 410 having a first surface and an opposite, second surface, one or more indentations 401 formed on the first surface of the first layer 410. One or more nanostructures 405 are directly formed on the locations of the indentations 401. In the embodiment as shown in FIG. 2(d), the first layer 410 is layer of VGF GaAs (100), and the nanostructures 405 are quantum dots of InGaAs.

These and other aspects of the present invention are more specifically described below.

### EXAMPLES AND IMPLEMENTATIONS OF THE INVENTION

Without intent to limit the scope of the invention, exemplary methods and their related results according to the embodiments of the present invention are given below. Note again that titles or subtitles may be used in the examples for convenience of a reader, which in no way should limit the scope of the invention. Moreover, certain theories are proposed and disclosed herein; however, in no way they, whether they are right or wrong, should limit the scope of the invention.

### Example 1

### Nanoscale Dislocation Patterning by Ultralow Load Indentation

In this exemplary embodiment, unlike the traditional use of nano-indentation for hardness measurement, the use of nano-indentation as a tool for the injection of dislocations at precise positions in semiconductors for the creation of periodic dislocation arrays was disclosed and investigated. The novelty of using nano-indentation is the ability to mechanically perturb the crystal lattice by accurate control of the applied stress, rate of deformation, and volume of dislocated regions. However, despite the potential of nano-indentation, this technique is dependant upon understanding material deformation mechanisms at ultralow loads. It has been shown that nano-indentation of semiconductors produces a range of defects in the crystal lattice including dislocations [8, 9], twinning [8, 10], phase transformations [8], and subsurface fracture [8, 11]. The suppression of these defects and phases is needed to enable nano-indentation as a dislocation patterning technique. But existing technologies of nano-indentation offers no satisfactory solution to address the need.

In one aspect of the present invention, the inventors seek to understand and explore the material deformation of GaAs at extremely low loads (<0.2 mN) that approach the threshold of plasticity. GaAs is a material of intense interest in the electronics industry because its direct band gap is suitable for ultra fast optical devices. Deformation of GaAs has been studied extensively in the past using high load (50-200 mN) [8, 12] as well as low load (0.2-8 mN) [9, 13, 14] indentation combined with TEM characterization of the deformation mechanisms. However, relatively less is known for loads in the lower regime of <0.2 mN, which is of interest for dislocation-assisted patterning. At such low loads the presence of only dislocations is expected, however due to the increased applied stress from the sharpness of the indenter (<40 nm) needed to produce nano-indents, it is highly likely that other defects are nucleated.

The deformation of GaAs(100) near nano-indented regions by cross-sectional TEM (XTEM) is investigated. The type of defects, the density of defects, preferred deformation mechanisms, and distribution pattern are analyzed as a function of load and in relation to their use for subsequent crystal growth and potential for QD patterning.

A Tribolndenter® (Hysitron Inc. of Minneapolis, Minn.) was utilized for ultralow-load nano-indentation. Nano-indentations were performed at room temperature with a diamond 90° NorthStar™ cube corner (tip radius <40 nm) indenter from Hysitron. Indents were made on epitaxial GaAs(100), which was prepared by growing a 500 nm buffer layer of GaAs by molecular beam epitaxy (MBE) on an epiready Si-doped GaAs(100) wafer, followed by deposition of a 100 nm AlAs (lattice-matched) marker layer, and a 300 nm GaAs top layer. Note that GaAs and AlAs have nearly identical elastic constants and have identical crystal structures, so this marker layer is expected to have little to no effect on the deformation response.

Indents can be made in the load-controlled mode of the instrument in the range of about 10 to 1,000 μN and were produced at: 400, 200, 100, and 50 μN. Groups of 20 indents were made in a linear fashion at each load with a spacing of 1 μm. Mesoscale (˜2-3 μm) marker indentations of 8000 μN were used to aid in locating the smaller indents. All indentations were performed with a 5 s loading period, followed by a 2 s hold at the peak load, and a 5 s unloading period. Atomic force microscopy (AFM) was used to image the indent impressions.

XTEM samples were prepared by the in situ ‘lift-out’ technique [15] using a FEI Strata 235 DualBeam focused ion beam (FIB)/scanning electron microscope (SEM) system.

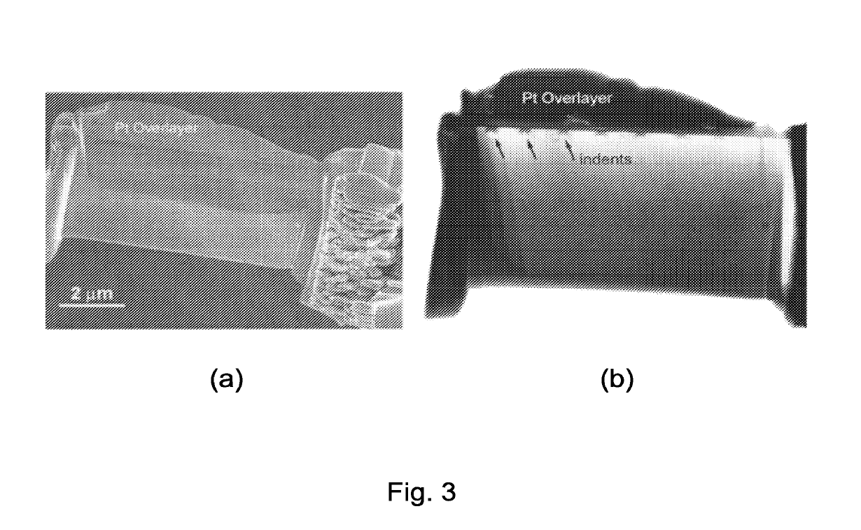

In order to protect the indents during ion milling, a layer of platinum was deposited. The indents were sectioned and thinned to <400 nm using progressively lower ion beam currents down to 100 pA. Images of a final thinned sample are shown in FIG. 3. The TEM used in this investigation was a JEOL JEM 3010 (JEOL Ltd., Tokyo 196-8558, Japan) operated at an accelerating voltage of 300 keV.

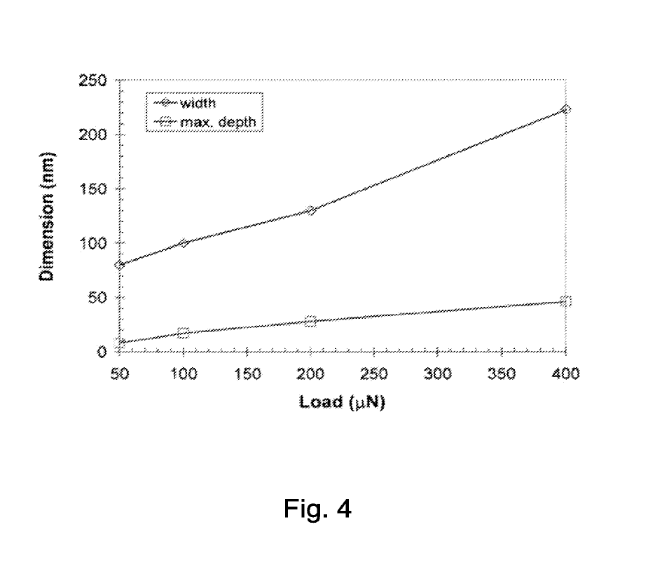

Measurement of the indent impressions by ex situ AFM imaging and subsequent sectional analysis for each loading condition is displayed in FIG. 4, where plots of residual indent dimensions in GaAs(100) measured by AFM are shown.

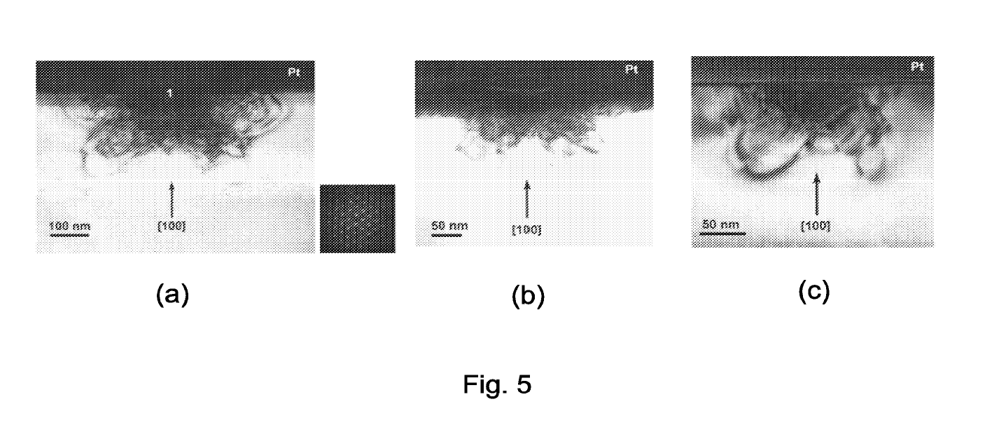

FIG. 5 shows bright-field TEM images of the (a) 400 μN, (b) 200 μN, and (c) 100 μN indents, respectively. The 100 μN indent was the smallest that could be successfully imaged. In all of the images the surface impression is not visible due to the protective over layer of deposited platinum. In FIG. 5(a), a hemispherical plastic zone populated by a large number of dislocations can be seen beneath the indent. Due to the complicated and dense structure of the dislocations we were unable to obtain any quantitative information of the Burgers vectors by performing g dot b tilting experiments. Protruding from the hemispherical plastic zone are two rosette arms about equal in length and extending <150 nm into the sample. Within these arms individual dislocation loops can be observed. The loops are perfect in nature and slip along the (111) planes in the <110> direction. This slip geometry is characteristic of zincblende semiconductors [16]. However, unlike previously seen GaAs indentation [9] no stacking faults were observed in the rosette arms, presumably due to the fact that the loads and indent depths in our experiment were significantly lower.

Also, there appears to be two shorter rosette arms closer to the top surface of the indent. Such a formation would be consistent with the four-fold rosette symmetry seen in plan view TEM of arms slipping in the four <110> directions [14]. All four arms appear to form a butterfly like configuration. It is important to note that no significant anisotropy in the rosette arms is observed, which is useful to make uniform dislocation templates for directed self-assembly. This is in contrast to recent work on higher load indentations, which reports an asymmetry in arm length and is experimentally correlated to the α(V-As) and β(III-Ga) nature of the dislocations in GaAs [17] In this study, images showed that the rosette arms are nearly equal in length.

Twinning deformation [8] and subsurface fracture [18] due to dislocation pile-up have been observed to occur in GaAs with loads of 50 mN or greater. However, no twinning or fracture was evident in the present images of these lower load indents. This is further substantiated by the selected area (zone axis) diffraction pattern of the indent, shown in the inset image of FIG. 5(a), taken over the central area labeled as (1). The fine spot pattern does not indicate the presence of any twinning, amorphization, or phase transformations. Similar “nano-beam” electron diffraction patterns obtained from the immediate subsurface area again indicated that the sample retained its diamond cubic crystal lattice throughout the indent. The lack of evidence of fracture is somewhat surprising considering that GaAs generally behaves like a brittle material at room temperature and that the acute angle and sharpness of the indenter tip generates a relatively high surface stress (up to about 14 GPa). There are no prior observations of sub-200 nm indents by cross-sectional TEM, and these results reveal that indentation deformation initiates by dislocation plasticity followed by the formation of other defects and/or phases at higher loads.

FIG. 5(b) shows a 200 μN indent cross section. Similar to the 400 μN case, two rosette arms are seen protruding from the hemispherical plastic zone extending ˜90 nm into the sample. Unlike the 400 μN case, only two arms are visible. This discovery along with the decrease in rosette arm length is indicative of the evolution of plastic deformation underneath the indent. The 100 μN cross section in FIG. 5(c) further substantiates the evolution of plastic deformation as the hemispherical plastic zone is clearly visible along with what appears to be the early stage formation of two rosette arms. The left arm is slightly longer and extends about 50 nm from the hemispherical zone. The strain state of the indents by high resolution measurement of atomic displacements and lattice parameters could not be performed due to the thickness of the prepared samples.

The present findings provide significant implications regarding the future use of indent induced dislocation strain fields as a patterning technique. A collective view of the three indents in this embodiment of the present invention indicates that GaAs plastically deforms solely by dislocation nucleation and propagation for loads less than 400 μN and indentation depths less than 50 nm. Unlike indents made at higher loads, the single phase deformation response (i.e., no fracture, amorphization, or other phase transformation) should allow for subsequent single crystal growth on top of the indent. Also, the TEM images show that the dislocation density and plastic zone size introduced into the material can be controlled by adjusting the applied load used to make the indent. The amount of work done by the indenter can be directly correlated to the energy needed to form a single dislocation loop.

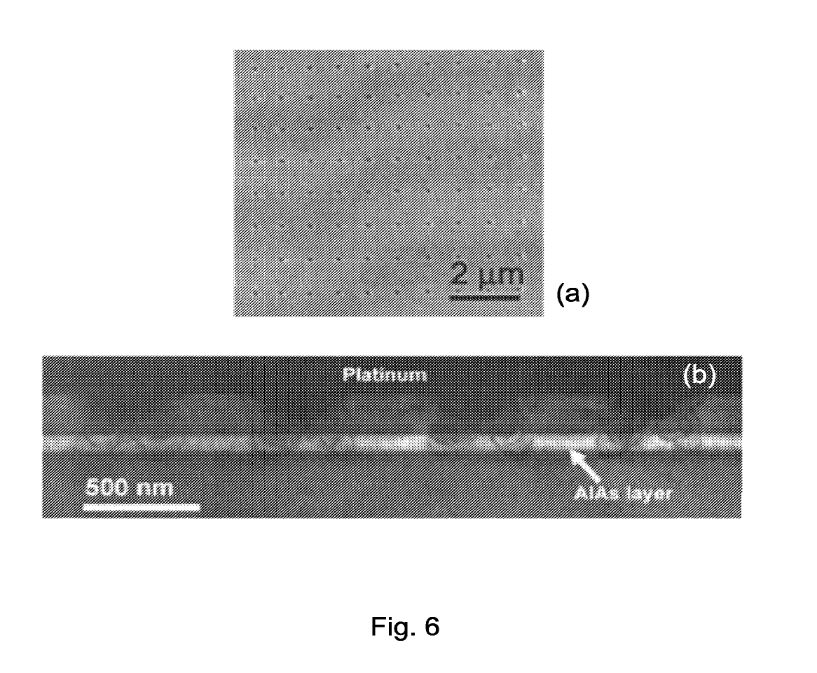

Furthermore, nano-indentation has the capability of making large-area periodic indent patterns, as shown in FIG. 6, with the spacing only limited by the resolution and accuracy of the piezodriven placement of indents. The size, depth, and spacing of indents can all be controlled well below 100 nm, allowing for precision nanoscale dislocation patterning.

In summary, the site-specific sample preparation of cross-sectioned nanofeatures (100 nm in size) has been achieved using the in situ “lift-out” technique. This allowed for observation of plastic deformation into the GaAs(100) surface as a function of load. Mechanical deformation is shown to proceed solely by the formation and propagation of dislocations, and not phase transformation. Also, it is shown that the dislocation density, size, and structure can be controlled by adjusting the nano-indentation load along with a carefully chosen tip shape and radius. It is concluded that nano-indentation is a viable technique for introducing nanosized volumes of dislocations and offers the potential for exploitation of the resulting elastic strain fields to enable directed self-assembly of QDs and possibly other nanostructures.

### Example 2

### Characterization of Ultra-Low Load (μN) Nanoindents in GaAs(100) Using a Cube Corner Tip

In this exemplary embodiment, a systematic investigation of the mechanical perturbation of the GaAs(100) surface for the patterned growth of quantum dots was initiated. One novel aspect of the present invention, as shown in this exemplary embodiment, is in the characterization of nano-indentations at ultra low load. Previous research has been done on high-load (50-200 mN) [27, 33] and low-load (0.2-8 mN) [25, 26, 34] nano-indentation. However, the loads required to produce indents at the quantum dot scale (sub-100 nm width) in GaAs are in a lower regime of <0.2 mN, which based upon the published literature is an area that has been studied very little and has not been previously studied using a cube corner indenter. The cube corner has the smallest available indenter tip radius (about 40 nm), which makes it suitable for the study of sub-100 nm indentations.

Furthermore, the use of a commercially available nano-indentation instrument, rather than an oscillating AFM tip, to make indents may be a superior technique for the fabrication of precision dot arrays. This is due to the increased control and precision provided by commercially available nanoindenters. The amount of load, rate of displacement, rate of loading, and tip size are closely controlled during nano-indentation, allowing for sophisticated study of material deformation at the nanoscale. Thus, the nanoindenter becomes a tool for the injection of highly localized defect sites, on which dots have been shown to nucleate.

In this exemplary embodiment, nano-indentation is performed on Si-doped (n-type) vertical gradient freeze (VGF) GaAs (100) and epitaxial GaAs(100) using a cube corner indenter. Ultra-low-load (<0.2 mN) nano-indentations are characterized as a function of applied load in order to determine the smallest indent that can be achieved and the perturbation of the GaAs(100) surface. Indentations of less than 200 nm in width are produced, and the mechanical properties of the two materials including hardness and elastic modulus are determined. The smallest indentations achieved are less than 60 nm in width and less than 2 nm deep. The width, depth, shape, and volume of the indents are determined as a function of applied load using atomic force microscopy (AFM). Also, the ratio of pile-up volume to indent volume is determined. The experimental findings are discussed in relation to existing theories of indentation and for the patterning of quantum dots.

### 2. Experimental Details

### 2.1. Hardness Measurement

The Nano Indenter II® (MTS Corp., Eden Prairie, Minn.) was used for hardness and elastic modulus measurement. Nano-indentation was performed at room temperature using a diamond cube corner indenter (tip radius of <100 nm). Indents were made on VGF epi-ready Si-doped GaAs(100) (supplied by American Xtal Technology Inc., Fremont, Calif.) and epitaxial GaAs(100) grown by molecular beam epitaxy (“MBE”). The epitaxial GaAs(100) sample was prepared by growing a 500 nm epitaxial GaAs layer on a VGF epi-ready Si-doped GaAs(100) wafer. Growth occurred at 490° C. with a growth rate of 0.72 mono layers per second (ML s⁻¹). These two materials were chosen since InAs quantum dots will be grown on them in a subsequent experiment. Prior to indentation, roughness analysis was performed on both sample surfaces by STM (Omicron Nano Technology USA, Eden Prairie, Minn.).

Indentations were made on each sample in the strain-rate controlled mode of the nanoindenter up to a maximum depth of 50 and 33 nm (max. loads reached <0.12 mN). The loading-unloading segments of each test includes the steps of (i) loading to maximum depth, (ii) holding for 5 s, (iii) unloading by 80%, (iv) holding for 60 s (used to calculate thermal drift), and (v) complete unloading. The strain rate (0.05) was the same during loading and unloading segments. The sample and instrument reached thermal equilibrium with thermal drift <0.05 nm s⁻¹ before indentation tests were performed.

Hardness and elastic modulus were approximated for both specimens utilizing continuous stiffness measurements taken from the loading segment of the load-displacement curve. The loading segment is used for all calculations since the sharpness of the cube corner indenter causes continuous penetration of the material during the hold segment at maximum load. This results in an erroneous extra displacement when calculating the contact area from the unloading data. Identical nano-indentation tests, with a maximum depth of about 300 nm, were performed on fused silica and were used as a standard for comparison of results.

### 2.2. Nanoindent Characterization

The TriboIndenter® (Hysitron Inc. of Minneapolis, Minn.) was utilized for ultra-low-load nano-indentation. Nano-indentations were performed at room temperature with a diamond 90° NorthStar™ cube corner (tip radius <40 nm) indenter. Indents were made on epitaxial GaAs(100), which was prepared by growing a 700 nm layer of GaAs by MBE on a VGF epi-ready Si-doped GaAs(100) (supplied by American Xtal Technology, Fremont, Calif.) wafer. MBE growth occurred at 580° C. with a growth rate of 0.69 mL s⁻¹.

Fifteen indents were produced in the load-controlled mode of the instrument using the following set of loading conditions: 5, 10, 15, 25, 50, 75, 100, 125, 150, 175, 200, 250, 300, 350, and 400 μN, respectively. The force resolution of the instrument was 100 nN.

Load, displacement, and time data were collected for each indentation. In addition, large marker indentations were produced on the sample at 9000 μN to aid in locating the smaller indents. Indentations were placed at a distance of at least ten times the indentation width apart to minimize strain interaction among indents. All in dentations were performed with a (i) 5 s loading period, (ii) followed by a 2 s hold at the peak load, and (iii) a 5 s unloading period. The sample and instrument reached thermal equilibrium with a thermal drift rate of 0.02 nm s⁻¹ before indentation tests were performed. Indentations were imaged with a Veeco/Digital Instruments Dimension 3000 AFM at room temperature to analyze the morphology of the resulting indentation and to measure indentation width, depth, and volume.

### 3. Results and Discussion

### 3.1. Surface Roughness

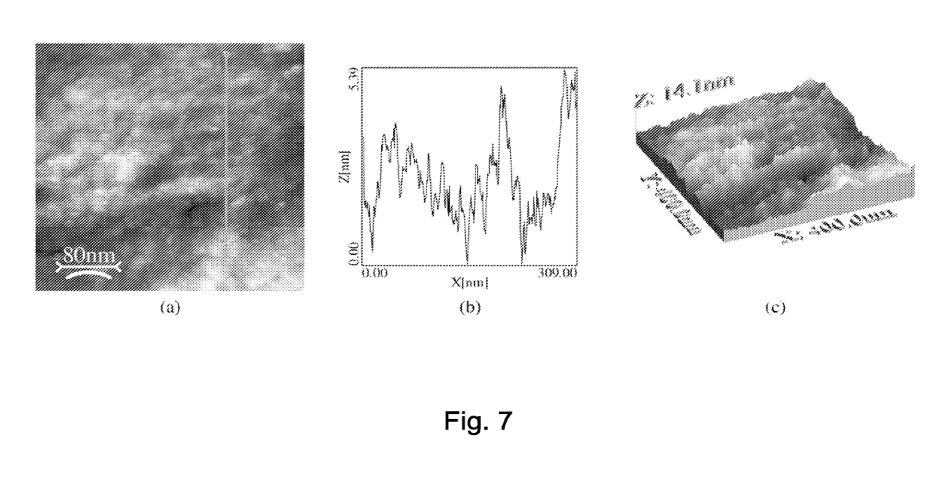

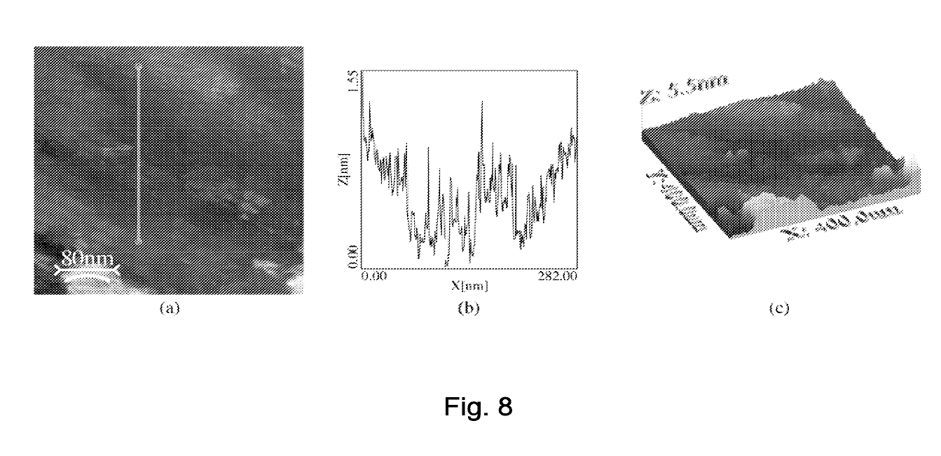

FIGS. 7 and 8 show images of the GaAs(100) surface obtained by STM, respectively. The VGF and MBE GaAs(100) surfaces have an rms roughness of about 2.0 and 0.6 nm respectively. The images show that an oxide layer is present on both surfaces. A native oxide layer is expected since the samples are not stored in a vacuum or reducing atmosphere. The rough oxide profile is highly uniform across the VGF sample as shown in the 3D surface view in FIG. 7(c). The MBE surface is much smoother with sporadic areas of oxide growth as shown in FIG. 8(c).

### 3.2. Hardness Measurement

One focus of the nano-indentation tests was to characterize the material properties and surface perturbation of the two samples. The hardness is taken as the ratio of the maximum load (P) to the projected area (Ap), namely

$$H = \frac{{P}_{max}}{{A}_{p}} . \qquad ( 1 )$$

The projected area is determined from a tip calibration function based on a constant modulus assumption following the method of Oliver and Pharr [35]. The reduced modulus is defined by

$${E}_{i} = S \frac{\sqrt{π}}{2 \sqrt{{A}_{p}}} \qquad ( 2 )$$

where S is the stiffness (dP/dh), which is measured using the continuous stiffness operation of the nanoindenter and is taken at the maximum point of loading.

The Young modulus is related to the reduced modulus and is calculated using the following equation:

$${E}_{1 T} = \frac{1 - {( {v}_{s} )}^{2}}{\frac{1}{{E}_{i}} - \frac{1 - {( {v}_{s} )}^{2}}{{E}_{i}}} \qquad ( 3 )$$

where Ei is the indenter modulus (about 1140 GPa for diamond indenters), vi is the Poisson ratio of the indenter (about 0.17 for diamond), and vs is the Poisson ratio of the substrate material (about 0.3 for GaAs).

TABLE 1
Nano-indentation hardness and modulus data.

| | | | | Reduced | Young's |
|---|---|---|---|---|---|
| | | | Hardness | modulus | modulus |
| | Material | Depth (nm) | (GPa) | (GPa) | (GPa) |
| 50 nm | VGF GaAs | 45.55 ± 0.75 | 9.79 ± 0.28 | 115.21 ± 2.78 | 116.56 ± 3.12 |
| max. | | | | | |
| depth | | | | | |
| | MBE GaAs | 45.29 ± 0.75 | 10.62 ± 0.30 | 117.35 ± 3.37 | 118.97 ± 3.81 |
| 33 nm | VGF GaAs | 27.31 ± 1.17 | 9.19 ± 0.43 | 115.26 ± 4.29 | 116.62 ± 4.82 |
| max. | | | | | |
| depth | | | | | |
| | MBE GaAs | 29.71 ± 0.43 | 10.28 ± 0.32 | 117.04 ± 5.14 | 118.63 ± 5.82 |
| Standard | Fused silica | 309.64 ± 0.41 | 9.35 ± 0.16 | 71.21 ± 2.62 | 73.74 ± 2.89 |

The results of the nano-indentation hardness tests are summarized in table 1. Average values for five indentations are given.

The data show that the hardness and elastic moduli of the MBE GaAs are higher than the VGF GaAs sample. The difference in hardness may be affected by the roughness of the two surfaces. The higher roughness of the VGF sample could act to reduce the mean contact pressure of the indenter by increasing the contact radius. This causes a decrease in displacement at a given load, resulting in overall reduced values for hardness and elastic moduli. In addition, it has been observed that the thickness of oxide on semiconductor surfaces may also act to reduce the mean contact pressure of the indenter [36].

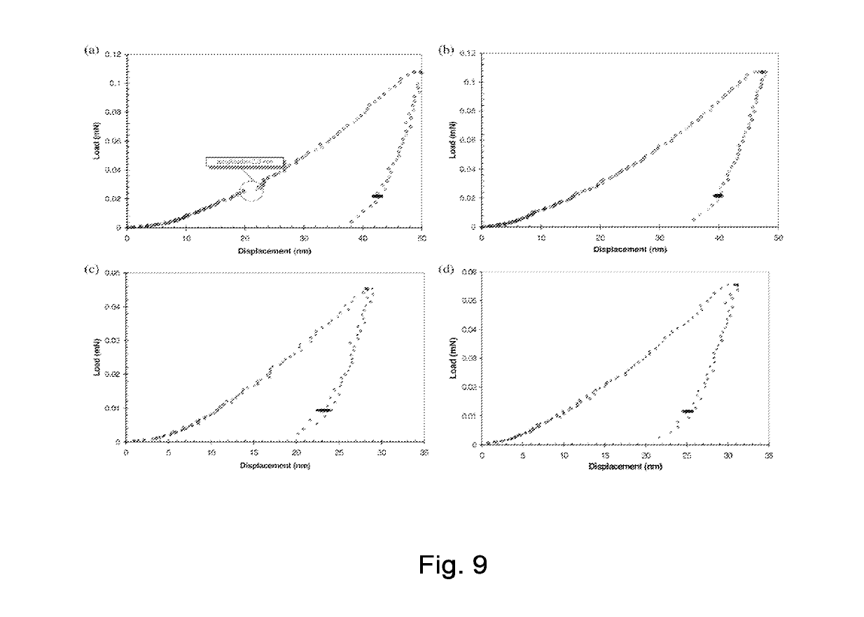

The fused silica data are used as a standard to gauge the accuracy of the results. The hardness and reduced modulus of fused silica have been well studied and are accepted to be approximately 9.25 and 69.6 GPa, respectively. The results obtained in this experiment are in agreement with accepted values [35]. Typical load-displacement curves for the two samples are given in FIG. 9, respectively Immediately apparent from the curves of the two samples is the presence of a discontinuity (pop-in) in the VGF sample. Such events were sometimes observed in the VGF sample, and occur between 0.02 and 0.06 mN (depth about 20 nm) with a pop-in amplitude of about 2.3 nm. Noise is apparent in the two curves. Plots of load versus time and displacement versus time reveal that the loading is smooth whereas the noise is in the displacement. The noise is likely due to the sharpness of the indenter tip, which results in penetration of the tip even at constant load. It is important to note that a pop-in event may be occurring in the MBE sample; however, the amplitude may be so small that it is indistinguishable from the noise in the present data.

Pop-in in CZ-grown GaAs has been readily observed at loads of about 0.4-1.5 mN, and has been attributed primarily to the nucleation of dislocations [25, 26, 33, 34]. Thus, this may be the point at which the onset of plasticity occurs. The extent of dislocations needs to be verified in both samples to determine if pop-in is associated with dislocation nucleation in the MBE sample. Also, pop-in has been associated with oxide breakthrough [36]; however, the about 20 nm depth (total penetration, i.e. elastic and plastic) at which pop-in is observed makes this assumption unlikely since the native oxide on the VGF wafer is expected to be much less than 20 nm (data taken from manufacturer).

### 3.3. Nano-Indentation Analysis

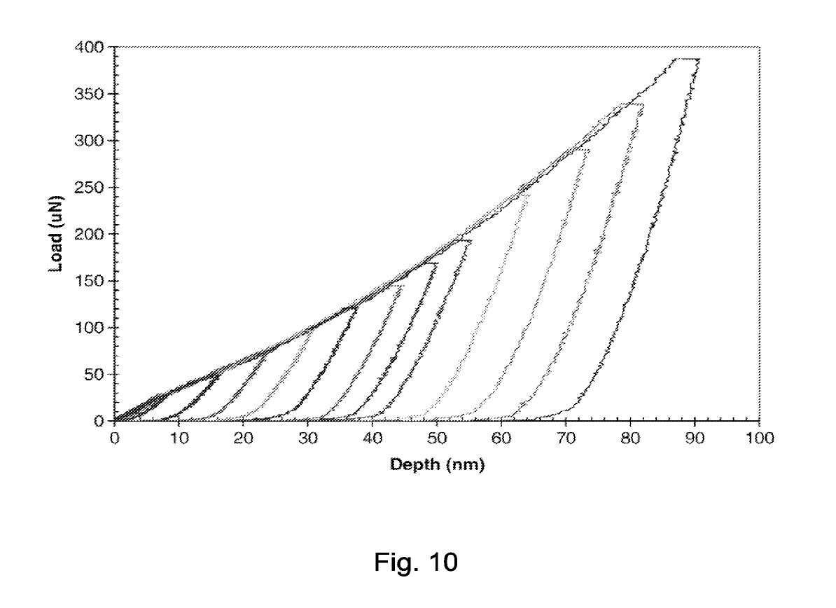

The load-depth curves for each indentation from 400 to 25 μN are shown in FIG. 10, respectively. The curves show the repeatability and consistency of the mechanical properties of the GaAs, as is evident by the overlapping of the loading portions of the curves.

Indentations ranged in size from about 200 to 50 nm in width and about 50 to 2 nm in depth. The size of the indentation is governed by the applied load, indenter tip geometry, tip radius, and depth of indentation. Also, applied stress is an important consideration in the nano-indentation process, because the stress must be greater than the critical stress for plastic deformation to be produced. Leipner calculates that the critical stress for dislocation nucleation in GaAs is about 6GPa [24, 25]. Thus, if the tip produces a stress higher than this, plastic deformation and defect nucleation can occur. In order to determine the minimum load required to produce plastic deformation in GaAs using a cube corner tip, Hertzian contact theory is utilized assuming tip rounding of the extremity.

It has been demonstrated that the nano-indentation load versus depth relationship for plastic deformation of GaAs agrees reasonably well with elastic Hertzian contact theory at low loads (<1.5mN) over depths from about 10 to 100 nm [37]. Also, from the calculation of the depth, the width of the indentation can be estimated using the known geometry of an ideal indenter.

The indentation width as a function of depth and projected contact area were derived to be the following equations for a cube corner indenter assuming a tip radius of 40 nm and that the tip geometry can be taken as spherical up to a depth of approximately ⅓rd of the tip radius:

w(d)=2\sqrt{(d²−2rd)}(d<r/3) (4)

Area=πd(2r−d)(d<r/3) (5)

Using Hertzian contact theory, the depth as a function of load varies according to:

$$Load = \frac{4}{3} {E}^{is} \sqrt{{rd}^{3}} \qquad ( 6 )$$

where r is the tip radius, d is the depth, and E^{is} is the combined tip-substrate modulus. Since the elastic modulus of diamond is much greater than that of GaAs, E^{is} is taken as the modulus of GaAs (˜99.5GPa) [38]. Substituting in the given values for the modulus and tip radius, and solving for depth as a function of load, the following equation is obtained:

$$d = {( \frac{Load}{2.653 \times {10}^{7}} )}^{\frac{2}{3}} d ( m ) , Load ( N ) . \qquad ( 7 )$$

Utilizing these equations ((4)-(7)), the lowest load required to produce plastic deformation, the transition load of the indent geometry from spherical to the three-sided pyramidal tip shape, and the smallest indent width and depth are calculated in table 2.

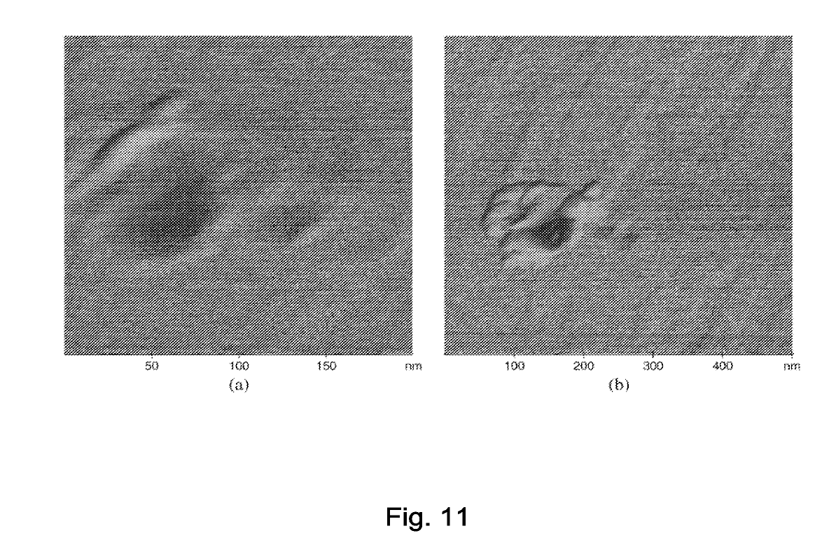

In comparing the experimentally produced low-load nano-indents with theory, it was found that plastic deformation could be produced at smaller loads than calculated above. The smallest load studied (about 5 μN) produced a distinct indentation of about 1.8 nm in depth, as shown in FIG. 11(a). In FIG. 11(b), it is observed that the indentation begins to take on the shape of the three-sided cube corner tip at 25 μN as indicated by the triangular indent area.

TABLE 2
Calculations of indentation parameters.
Indentation parameters

| | |
|---|---|
| Lowest load required (μN) | 8 |
| Transition load (μN) | 226 |
| Minimum width (nm) | 40 |
| Minimum depth (nm) | 4 |

TABLE 3
Residual indentation width and depth for each load.

| Load (μN) | Width (nm) | Depth (nm) |
|---|---|---|
| 400 | 223 | 46.5 |
| 350 | 199 | 44.8 |
| 300 | 174 | 39.5 |
| 250 | 154 | 36.1 |
| 200 | 133 | 28.1 |
| 175 | 131 | 24.4 |
| 150 | 127 | 18.8 |
| 125 | 122 | 16.3 |
| 100 | 111 | 17.1 |
| 75 | 106 | 12 |
| 50 | 80 | 8.4 |
| 25 | 68 | 3.5 |
| 15 | 57 | 2.5 |
| 10 | 58 | 2.8 |
| 5 | 56 | 1.8 |

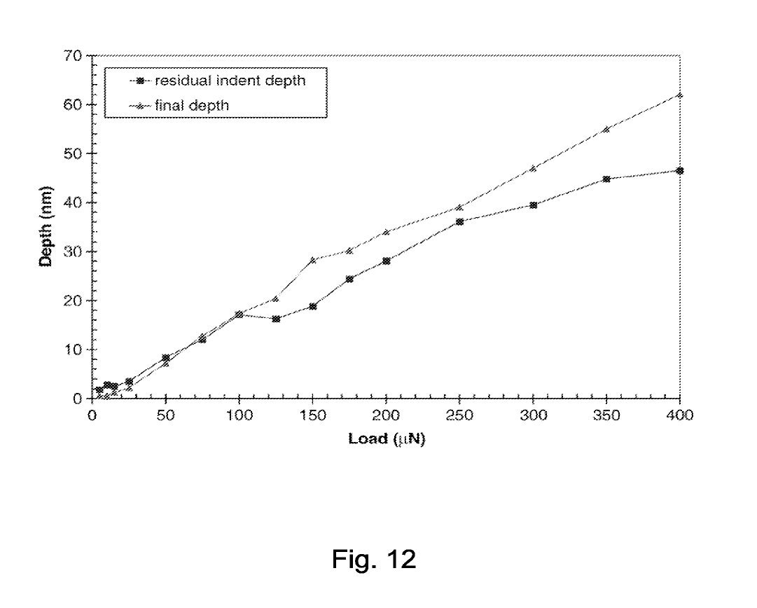

In both loading conditions the measured residual depth was lower than predicted. However, this is understandable since the above calculations did not account for relaxation of the indent. Considerable relaxation of the indents is apparent throughout the loads as indicated in FIG. 12 by the deviation in the load-depth curves' final depth and the residual indent depth measured by AFM.

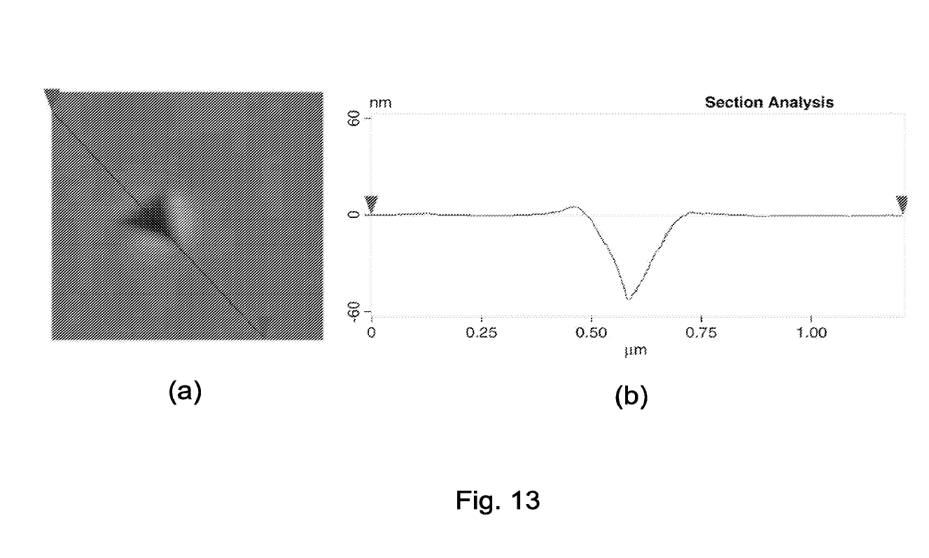

The residual depth and width for each indent measured with the AFM are given in table 3. Typical sectional profiles of the indents used for measurement are shown in FIG. 13.

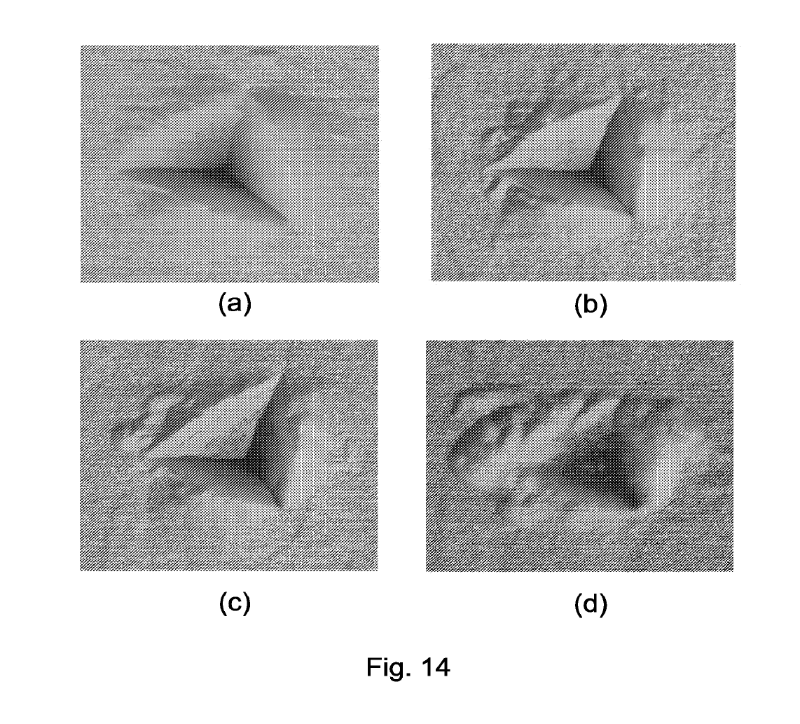

FIG. 14 shows images of several indents, and it is observed that a significant amount of pile-up occurred at loads above 75 μN. Pile-up refers to the material that is pushed up above the flat plane of the substrate surface.

The pile-up behavior has been explained by Johnson's [39] expanding cavity model, whereby the plastic zone beneath theindenter expands under increasing load. Eventually the plastic zone bursts out to the free surface and the displaced material is free to move by plastic flow above the surface of the indentation. Utilizing this model the volume of the displaced material should be conserved, thus the indent volume should be equal to the pile-up volume.

The volume of the indent was calculated using AFM NanoScope™ software (Veeco/Digital Instruments) by inverting the image and utilizing the “bearing” function. This allows the software to calculate volumes of material above a given height. The volume of pile-up is similarly determined.

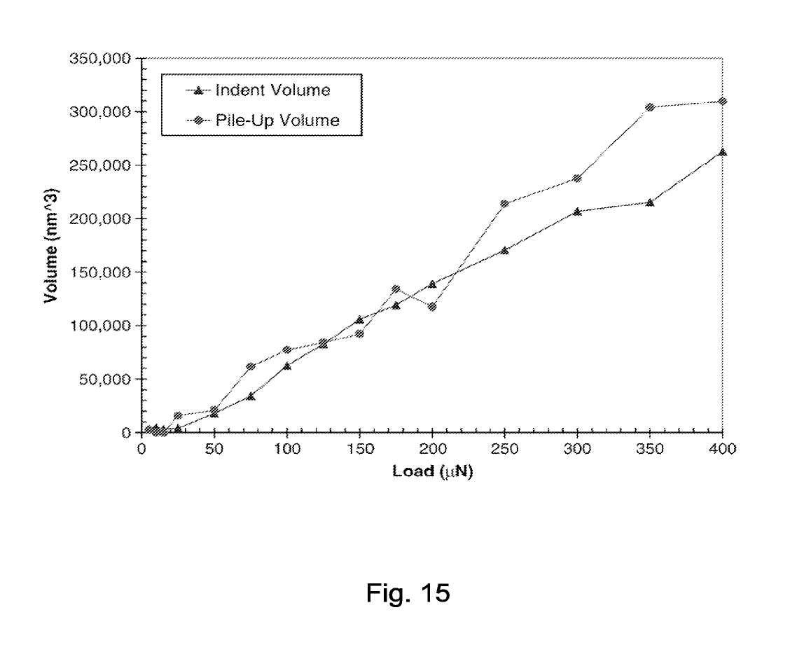

It is observed in FIG. 15 that the displaced material is roughly conserved up to loads of 200 μN. Above 200 μN, the pile-up volume is considerably larger than the indent volume, which is somewhat of an anomaly. The reason for this may be that the method of measurement may be inaccurate or the result of AFM artifacts inherent to the mechanical mechanism of imaging. However, a previous study [40] utilizing STM characterization of indentations also found that pile-up volume was larger than the indent volume, which may indicate a materials issue.

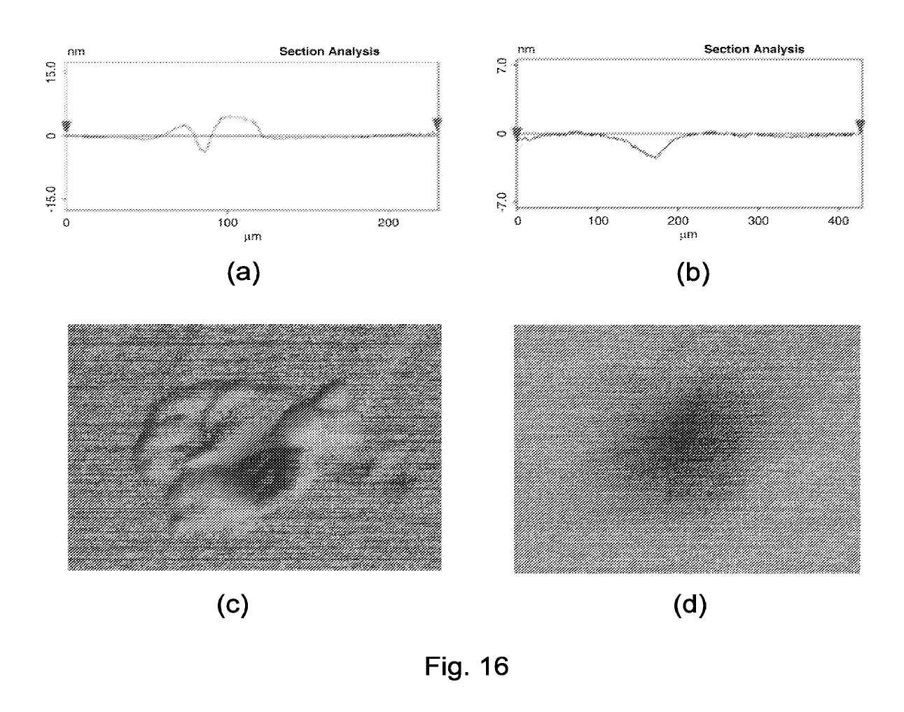

In addition, a transition point from an indentation with significant pile-up to one that sinks into the plane was observed between 25 and 15 μN. This is shown in FIG. 16 by the AFM cross-section views of the 25 μN indentation and 15 μN indentations, respectively.

The 25 μN indentation has significant material raised include annealing of the samples and re-evaluation of the above the plane. This is an interesting result in that subsurface nano-indentation properties. imaging of both samples may reveal the size of the plastic zone, which would determine how well the experiment agrees with the expanding cavity model at low loads. Future work will include TEM imaging of such a phenomenon.

In summary, the loads required to produce sub-100 nm indentations in GaAs are <0.2 μN. Indentations less than 60 nm in width and 2 nm deep have been produced using a sharp cube corner tip, and mechanical properties of VGF and MBE GaAs(100) including hardness and elastic modulus were calculated and compared. Pop-in is observed to occur in the VGF sample, and it is speculated that this may be due to the onset of plasticity. Indentations are primarily spherical at loads less than 25 μN and begin to take on the shape of the three-sided cube corner with observed pile-up at the edges for loads larger than 25 μN. Indented regions were shown to relax after indentation.

Quantum dots are on the order of about 10-100 nm in width. Therefore, it is discovered that the indentations at 15 μN and less will be the best size and shape for quantum dot growth; this is because there is very little pile-up and no sharp edges, which may be an indication of non-eccentric lattice damage allowing for a well defined strain field. These indents produced at <15 μN were less than 58 nm in width and 2.5 nm in depth. In order to grow quantum dots at the nano-indentation sites, the indented GaAs wafer would be placed into the MBE chamber and brought up to a temperature around 600° C. before growth of the InAs layer. It is further discovered that the shape of the indentations may change, as an effect of annealing at the MBE growth conditions. By utilizing the methods disclosed above, nanostructures such as quantum dots can be grown at the nano-indentation sites or sites corresponding to the nano-indentation sites.

While there has been shown several and alternate embodiments of the present invention, it is to be understood that certain changes can be made as would be known to one skilled in the art without departing from the underlying scope of the invention as is discussed and set forth above and below including claims. Furthermore, the embodiments described above and claims set forth below are only intended to illustrate the principles of the present invention and are not intended to limit the scope of the invention to the disclosed elements.

### REFERENCE LIST

[1]. N. Kirstaeder, N. N. Ledenstov, M. Grundmann, D. Bimberg, V. M. Ustinov, S. S. Ruvimov, M. V. Maximov, P. S. Kop'ev, Zh. I. Alferov, U. Richter, P. Werner, U. Gosele, and J. Heydenreich, Electron. Lett. 30, 1416 (1994).
[2]. S. K. Jung, C. K. Hyon, J. H. Park, S. W. Hwang, D. Ahm, M. H. Son, B. D. Min, Y. Kim, and E. K. Kim, Appl. Phys. Lett. 75, 1167 (1999).
[3]. D. Leonard, M. Krishnamurthy, C. M. Reaves, S. P. Denbaars, and P. M. Petroff, Appl. Phys. Lett. 63, 3203 (1993).
[4]. R. Leon, S. Chaparo, C. Johnson, X. Navarro, Y. Zhang, J. Siegert, S. Marcinkevicius, X. Liao, and J. Zou, J. Appl. Phys. 91, 5826 (2002).
[5]. G. Springholz and K. Wiesauer, Phys. Rev. Lett. 88, 015507 (2002).
[6]. F. Leroy, J. Eymery, and P. Gentile, Appl. Phys. Lett. 80, 3078 (2002).
[7]. F. M. Ross, IBM J. Res. Dev. 44, 489 (2000).
[8]. S. J. Lloyd, J. M. Molina-Aldareguia, and W. J. Clegg, J. Mater. Res. 16, 3347 (2001).
[9]. E. LeBourhis and G. Patriarche, Philos. Mag. Lett. 79, 805 (1999).
[10]. E. LeBourhis, G. Patriarche, L. Largeau, and J. P. Riviere, J. Mater. Res. 19, 131 (2004).
[11]. Z. C. Li, L. Liu, L. He, and Y. B. Xu, J. Mater. Res. 16, 2845 (2001).
[12]. G. Barbato, S. Desogus, A. Germak, and G. B. Picotto, J. Vac. Sci. Technol. B 12, 1738 (1994).
[13]. H. S. Leipner, D. Lorenz, A. Zecker, H. Lei, and P. Grau, Physica B 308-310, 446 (2001).
[14]. H. S. Leipner, D. Lorenz, A. Zecker, and P. Grau, Phys. Status Solidi B 183, R4 (2001).
[15]. B. I. Prenitzer, L. A. Giannuzzi, K. Newman, S. R. Brown, R. B. Irwin, T. L. Shofner, and F. A. Stevie, Metall. Mater. Trans. A 29, 2399 (1998).
[16]. S. Mahajan, Handbook on Semiconductors (Elsevier Science, North-Holland, 1994).
[17]. L. Largeau, G. Patriarche, F. Glas, and E. LeBourhis, J. Appl. Phys. 95, 3984 (2004).
[18]. J. E. Bradby, J. S. Williams, J. Wong-Leung, M. V. Swain, and P. Munroe, Appl. Phys. Lett. 78, 3235 (2001).
[19]. Konkar A, Heitz R, Ramachandran T R, Chen P and Madhukar A 1998 Fabrication of strained InAs island ensembles on nonplanar patterned GaAs(001) substrates J. Vac. Sci. Technol. B 16 1334-8
[20]. Jeppesen S, Miller M, Hessman D, Kowalski B, Maximov I and Samuelson L 1996 Assembling strained InAs islands on patterned GaAs substrates with chemical beam epitaxy Appl. Phys. Lett. 68 2228-30
[21]. Zhang R, Tsui R, Shiralagi K, Convey D and Goronkin H 1998 Selective formation and alignment of InAs quantum dots overmesa stripes along the [011] and [001] direction on GaAs(100) substrates Appl. Phys. Lett. 73 505-7
[22]. Ishikawa T, Nishimura T, Kohmoto S and Asakawa K 2000 Site-controlled InAs single quantum-dot structures on GaAs surfaces patterned by in situ electron-beam lithography Appl. Phys. Lett. 76 167-9
[23]. Kasu M, Makimoto T and Kobayashi N 1997 Selective-area GaAs growth using nitrogen passivation and scanning-tunneling-microscopy modification on a nanometer scale Appl. Phys. Lett. 70 1161
[24]. Hyon C K, Choi S C, Song S H, Hwang S W, Son M H, AhnD, Park Y J and Kim E K 2000 Application of atomic force microscope direct patterning to selective positioning of InAs quantum dots on GaAs Appl. Phys. Lett. 77 2607
[25]. LeBourhis E and Patriarche G 1999 Transmission electron microscopy observations of low-load indents in GaAs Phil. Mag. Lett. 79 805-12
[26]. Leipner H S, Lorenz D, Zecker A, Lei H and Grau P 2001 Nano-indentation pop-in effect in semiconductors Physica B 308-310 446-9
[27]. Lloyd S J, Molina-Aldareguia J M and Clegg W J 2001 Deformation under nanoindents in Si, Ge, and GaAs examined through transmission electron microscopy J. Mater. Res. 16 3347
[28]. Li Z C, Liu L, He L L and Xu Y B 2001 Shear-activated indentation crack in GaAs single crystal J. Mater. Res. 16 2845-9
[29]. Leon R, Chaparo S, Johnson C, Navarro X, Zhang Y, Siegert J, Marcinkevicius S, Liao X and Zou J 2002 Dislocation-induced spatial ordering of InAs quantum dots: effects on optical properties J. Appl. Phys. 91 5826-30
[30]. Leroy F, Eymery J and Gentile P 2002 Ordering of Ge quantum dots with buried Si dislocation networks Appl. Phys. Lett. 80 3078-80
[31]. Ross F M 2000 Growth processes and phase transformations studied by in situ transmission electron microscopy IBM J. Res. Dev. 44 489-501
[32]. Shiryaev S Y, Jensen F, Hansen J, Petersen J and Larsen A 1997 Nanoscale structuring by misfit dislocations in SiGe/Si epitaxial systems Phys. Rev. Lett. 78 503-6
[33]. Barbato G, Desogus S, Germak A and Picotto G B 1994 Microhardness measurements by scanning tunneling microscope J. Vac. Sci. Technol. B 12 1738
[34]. Leipner H S, Lorenz D, Zecker A and Grau P 2001 Dislocation-related pop-in effect in gallium arsenide Phys. Status Solidi 183 R4-6
[35]. Oliver W C and Pharr G M 1992 An improved technique for determining hardness and elastic modulus using load and displacement sensing indentation experiments J. Mater. Res. 7 1564
[36]. Asif S A, Wahl K J and Colton R J 2000 The influence of oxide and adsorbates on the nanomechanical response of silicon wafers J. Mater. Res. 15 546-53
[37]. Lilleoden E T, Bonin W, Nelson J, Wyrobek J T and Gerberich W W 1995 In situ imaging of μNload indents into GaAs J. Mater. Res. 10 2162
[38]. Properties of Gallium Arsenide 1990 (EMIS Data Reviews Series No. 2)(London: INSPEC)
[39]. Johnson K L 1985 Contact Mechanics (Cambridge: Cambridge University Press) p 451
[40]. Walls M, Chaudhri M and Tang T 1992 STM profilometry of low-load Vickers indentations in a silicon crystal J. Phys. D: Appl. Phys. 25 500-7.

What is claimed is:

1. A method for patterning nanostructures in a semiconductor heterostructure having at least a first layer and a second layer, wherein the first layer has a first surface and an opposite, second surface, the second layer has a first surface and an opposite, second surface, and the first layer is deposited over the second layer such that the second surface of the first layer is proximate to the first surface of the second layer, comprising the steps of:
(a) making indentations in a pattern on the first surface of the first layer of the semiconductor heterostructure;
(b) bonding the semiconductor heterostructure to a support substrate such that the first surface of the first layer of the semiconductor heterostructure is faced to the support substrate;
(c) etching off the second layer of the semiconductor heterostructure; and
(d) depositing a third layer over the second surface of the first layer of the semiconductor heterostructure to allow nanostructures to grow in a pattern thereon a surface of the third layer which is distant away from the second surface of the first layer.

2. The method of claim 1, wherein the making step comprises the steps of:
(a) positioning an indenter over the first surface of the first layer of the semiconductor heterostructure at a desired position;
(b) applying a load to the indenter to produce an indentation at the desired position; and
(c) repeating steps (a) and (b) to make indentations in a desired pattern,
wherein the nanostructures are grown in a pattern corresponding to the indentations in a desired pattern.

3. The method of claim 2, wherein the indenter comprises a nanoscale tip capable of producing a desired indention.

4. The method of claim 3, wherein the nanoscale tip has an end profile of one of a circle, square, triangle, rhombus, pyramid, cube corner, polygon and a desired geometric shape.

5. The method of claim 2, wherein the load is less than a threshold value.

6. The method of claim 1, wherein the nanostructures comprise quantum dots, nanowires, nanorods, or nanotubes.

7. The method of claim 1, wherein the first to third layers comprise a GaAs layer, an AlAs layer and an InAs layer, respectively.

8. The method of claim 1, further comprising the steps of
(a) depositing a fourth layer over the grown nanostructures on the third layer; and
(b) depositing a fifth layer over the fourth layer to allow nanostructures to grow 3-dimensionally therein.

9. The method of claim 8, wherein the fourth and fifth layers comprise a GaAs layer and an InAs layer, respectively.

10. A semiconductor heterostructure with nanostructures in a pattern formed according to the method of claim 1.

11. An apparatus for patterning nanostructures in a semiconductor heterostructure, comprising:
(a) a positioning device capable of moving in three dimensions;
(b) an indenter coupled to the position device;
(c) a load device for applying a load to the indenter for producing an indentation on a surface of the semiconductor heterostructure;
(d) a controller in communication with the positioning device for controlling the indenter to move to a desired position over the surface of the semiconductor heterostructure to produce an indentation thereon; and
(e) means for depositing a semiconductor layer over the indented surface of the semiconductor heterostructure as to allow nanostructures to grow from another surface of the semiconductor heterostructure that is opposite to the indented surface.

12. The apparatus of claim 11, wherein the semiconductor heterostructure comprises:
(a) a GaAs buffer layer having a thickness substantially around 500 nm grown on an epiready Si-doped GaAs(100) wafer;
(b) an AlAs marker layer having a thickness substantially around 100 nm deposited on the GaAs buffer layer; and
(c) a GaAs top layer having a thickness substantially around 300 nm deposited on the AlAs marker layer.

13. The apparatus of claim 11, wherein the indenter comprises a nanoscale tip capable of producing a desired indention, and wherein the nanoscale tip has an end profile of one of a circle, square, triangle, rhombus, pyramid, cube corner, polygon and a desired geometric shape.

14. A method for patterning nanostructures in a semiconductor, comprising the steps of:
(a) indenting a surface of the semiconductor to make nano-sized volumes of dislocations thereon in a desired pattern; and
(b) forming a semiconductor layer over the indented surface of the semiconductor to allow nanostructures to grow corresponding to the desired pattern on another surface of the semiconductor that is opposite to the indented surface.

15. The method of claim 14, wherein the indenting step is performed with an indenter.

16. A semiconductor with nanostructures in a pattern formed according to the method of claim 14.

17. A method for growing nanostructures in a pattern with a semiconductor heterostructure having at least a first layer and a second layer, wherein the first layer has a first surface and an opposite, second surface, the second layer has a first surface and an opposite, second surface, and the first layer is deposited over the second layer such that the second surface of the first layer is proximate to the first surface of the second layer, comprising the steps of:
(a) making indentations in a pattern on the first surface of the first layer of the semiconductor heterostructure; and
(b) growing nanostructures at a surface that is separated from the first surface of the first layer of the semiconductor heterostructure, wherein each nanostructure grows at a position corresponding to one of the indentations.

18. The method of claim 17, wherein the step of growing nanostructures comprises the steps of (a) bonding a third layer with the first layer; (b) depositing a fourth layer over the third layer; and (c) growing nanostructures at a surface of the fourth layer that is distant away and separated from the first layer.

19. The method of claim 18, wherein the nanostructures as grown form a pattern that is substantially identical to the pattern of the indentations.

20. The method of claim 18, wherein the third and fourth layers comprise a GaAs layer and an InAs layer, respectively, further comprising the steps of
(a) depositing a fifth layer of GaAs over the grown nanostructures on the fourth layer of InAs; and
(b) depositing a sixth layer of InAs over the fifth layer of GaAs to allow nanostructures to grow therein at positions corresponding to the positions of the nanostructures on the fourth layer of InAs, wherein the fifth layer and sixth layer form a combination of a layer of GaAs and a layer of InAs with nanostructures grown on the layer of InAs.

21. The method of claim 20, further comprising the step of depositing additional a combination of a layer of GaAs and a layer of InAs over the last combination of a layer of GaAs and a layer of InAs.

22. A semiconductor heterostructure with nanostructures formed according to the method of claim 21.

23. A semiconductor heterostructure with nanostructures in a pattern formed according to the method of claim 17.

24. A semiconductor heterostructure formed with nanostructures, comprising:
(a) a first layer having a first surface and an opposite, second surface;
(b) a second layer having a first surface and an opposite, second surface, wherein the first layer is deposited over the second layer such that the second surface of the first layer is distant from the second layer;
(c) at least one indentation formed on the first surface of the first layer;
(d) a third layer deposited over the second surface of the first layer, wherein the third layer has a first surface and an opposite, second surface, and the third layer is deposited over the second surface of the first layer such that the second surface of the third layer is in contact with the second surface of the first layer; and
(e) at least one nanostructure formed on the first surface of the third layer and at a position corresponding to that of at least one indentation formed on the first surface of the first layer.

25. The semiconductor heterostructure of claim 24, wherein the at least one indentation formed on the first surface of the first layer comprises one or more indentations formed in a pattern or an array.

26. The semiconductor heterostructure of claim 25, wherein the at least one nanostructure comprises one or more nanostructures formed in a pattern or an array corresponding to the pattern or array the one or more indentations formed.

27. The semiconductor heterostructure of claim 26, wherein the nanostructures comprise quantum dots, nanowires, nanorods, or nanotubes.

28. The semiconductor heterostructure of claim 24, wherein the first to third layers comprise a GaAs layer, an AlAs layer and an InAs layer, respectively.

29. A semiconductor heterostructure formed with nanostructures, comprising:
(a) a first layer having a first surface and an opposite, second surface;
(b) at least one indentation formed on the first surface of the first layer;
(c) a second layer formed over the first surface of the first layer, wherein the second layer is a buffer layer;
(d) a layered structure formed over the second layer, wherein the layered structure has at least a first layer of a first semiconductor, a second layer of the first semiconductor, and a layer of a second semiconductor positioned between the first layer and the second layer of the first semiconductor; and
(e) at least one nanostructure formed on each of a first surface of the first layer and the second layer of the first semiconductor, respectively, and at a position corresponding to that of at least one indentation formed on the first surface of the first layer.

30. The semiconductor heterostructure of claim 29, wherein the at least one indentation formed on the first surface of the first layer comprises one or more indentations formed in a pattern or an array.

31. The semiconductor heterostructure of claim 29, wherein the at least one nanostructure comprises one or more nanostructures formed in a pattern or an array corresponding to the pattern or array the one or more indentations formed.

32. The semiconductor heterostructure of claim 31, wherein the nanostructures comprise quantum dots, nanowires, nanorods, or nanotubes.

33. The semiconductor heterostructure of claim 29, wherein the first layer comprises a layer of MBE GaAs or VGF GaAs, the second layer comprises a layer of GaAs, the first semiconductor comprises InAs, and the second semiconductor comprises GaAs, respectively.

34. The semiconductor heterostructure of claim 29, comprising a super-lattice structure.
